(19) United States
(12) Patent Application Publication
(10) Pub. No.: US 2026/0098878 A1
(43) Pub. Date: Apr. 9, 2026

(54) CURRENT MONITOR MOUNTABLE TO A LIVE ELECTRICAL CONDUCTOR

(71) Applicant: Schweitzer Engineering Laboratories, Inc., Pullman, WA (US)

(72) Inventors: Eric M. Sawyer, Moscow, ID (US); Samuel D. Kusch, Lafayette, IN (US); Eric Ryan, Spokane Valley, WA (US); Luis Rodriguez Torres, Soledad de Graciano Sánchez (MX); Robert George, Coeur d'Alene, ID (US); Miralem Cosic, Spokane, WA (US); Eugene K. Weaver, Chicago, IL (US)

(73) Assignee: Schweitzer Engineering Laboratories, Inc., Pullman, WA (US)

(21) Appl. No.: 18/909,689

(22) Filed: Oct. 8, 2024

(51) Int. Cl. G01R 15/18; G01R 19/00; G01R 31/58

(52) U.S. Cl. CPC G01R 15/181; G01R 19/0092; G01R 31/58

(57) ABSTRACT

The present application discloses a current monitor mountable to an energized electrical conductor in an electric power system and related methods. In one embodiment, a current monitor comprises a housing, a first moveable arm coupled to the housing, and a second moveable arm coupled to the housing. The first moveable arm and the second moveable arm are configurable in an open configuration and a closed configuration. A current sensor is disposed in the moveable first arm and the second moveable arm and generates a signal output representing a current flow in the energized electrical conductor. The first moveable arm and the second moveable arm form a channel to receive the electrical conductor in the open configuration and transition to a closed configuration in which the first moveable arm and the second moveable arm substantially surround the electrical conductor in response to the electrical conductor entering the channel.

### TECHNICAL FIELD

This disclosure relates to monitoring an electric current in a conductor of electric power systems. More specifically, but not exclusively, the present disclosure relates to a monitoring device comprising a current monitor that may be mounted to a live electrical conductor using a hot stick.

### BRIEF DESCRIPTION OF THE DRAWINGS

Non-limiting and non-exhaustive embodiments of the disclosure are described, including various embodiments of the disclosure with reference to the figures, in which:

FIG. 1 illustrates a perspective view of a current sensor in an open configuration consistent with embodiments of the present disclosure.

FIG. 2 illustrates a perspective view of a current sensor comprising a fault indicator consistent with embodiments of the present disclosure.

FIG. 3 illustrates a cross-sectional view of a current sensor in an open configuration consistent with embodiments of the present disclosure.

FIG. 4A illustrates a bottom view of a current sensor in a closed configuration consistent with embodiments of the present disclosure.

FIG. 4B illustrates a bottom view of the current sensor of FIG. 4A in an open configuration consistent with embodiments of the present disclosure.

FIG. 4C illustrates a bottom view of the current sensor of FIG. 4A in an open configuration and receiving a conductor in a channel consistent with embodiments of the present disclosure.

FIG. 4D illustrates a bottom view of the current sensor of FIG. 4A in a closed configuration and mounted to a conductor consistent with embodiments of the present disclosure.

FIG. 5 is a flowchart of an example method of mounting a current monitor to an energized electrical conductor in an electric power system consistent with embodiments of the present disclosure.

The following description provides numerous specific details for a thorough understanding of the various embodiments disclosed herein. However, those skilled in the art will recognize that the systems and methods disclosed herein can be practiced without one or more of the specific details, or with other methods, components, materials, etc. In addition, in some cases, well-known structures, materials, or operations may not be shown or described in detail to avoid obscuring aspects of the disclosure. Furthermore, the described features, structures, or characteristics may be combined in any suitable manner in one or more alternative embodiments.

### DETAILED DESCRIPTION

Electric power systems generate, transmit, and distribute electric power to loads and serve as an important part of critical infrastructure. Various types of equipment may monitor and protect electric power systems and equipment. Protection relays may analyze the parameters of an electric power system to implement protective functions. The primary protective relays may communicate with various other supervisory devices, such as automation systems, monitoring systems, supervisory (SCADA) systems, and other intelligent electronic devices (IEDs). IEDs may collect data from various devices within an electric power system and monitor, control, automate, and/or protect such devices.

As used herein, an IED may refer to any microprocessor-based device that monitors, controls, automates, and/or protects monitored equipment within a system. Such devices may include, for example, differential relays, distance relays, directional relays, feeder relays, overcurrent relays, voltage regulator controls, voltage relays, breaker failure relays, generator relays, motor relays, remote terminal units, automation controllers, bay controllers, meters, recloser controls, communications processors, computing platforms, programmable logic controllers (PLCs), programmable automation controllers, input and output modules, and the like. The term IED may be used to describe an individual IED or a system comprising multiple IEDs. Further, IEDs may include sensors (e.g., voltage sensors, current sensors, contact sensors, status sensors, light sensors, tension sensors, etc.) that provide information about the electric power system.

Current sensors may be used throughout an electric power system to monitor the flow of electrical current and maintain current flows within specific ranges. Excessive current flow, or an over-current condition, may cause damage to equipment in the electric power system. Upon detection of an over-current condition, the flow of electric current may be interrupted by a protective action (e.g., tripping a breaker to electrically isolate a portion of the electric power system). Adding current monitors to an electric power system may provide additional information about the flow of electrical energy in the system and may provide a variety of benefits to the operator of such an electric power system.

Current sensors commonly loop around electrical conductors, and as such, the installation of a current sensor commonly requires that a line be de-energized before a current sensor is installed. In particular, Rogowski coils commonly loop around the conductor and the ends are fastened together. Installing such devices requires manual dexterity and close proximity to the electrical conductor. Operators of electric power systems seek to provide continuous and reliable electrical power to their customers; however, such systems must also operate safely and economically.

A current monitor that can be installed on an energized electrical conductor may provide several advantages. For example, such a current monitor may allow an operator to avoid interruption of electrical power delivery during installation, thus increasing the reliability of the electric power system. Moreover, such current monitors may provide improved electric power system monitoring. A finer level of granularity may be achieved by increasing the number of current monitors, thus allowing an electric power system operator to reduce the impact of protective actions to resolve over-current conditions. Further, such information may be useful for identifying trends within a power system, identifying potential problems, and/or improving power forecasting and planning.

The embodiments of the disclosure will be best understood by reference to the drawings. It will be readily understood that the components of the disclosed embodiments, as generally described and illustrated in the figures herein, could be arranged and designed in a wide variety of different configurations. Thus, the following detailed description of the embodiments of the systems and methods of the disclosure is not intended to limit the scope of the disclosure, as claimed, but is merely representative of possible embodiments of the disclosure. In addition, the steps of a method do not necessarily need to be executed in any specific order or even sequentially, nor do the steps need to be executed only once unless otherwise specified.

In some cases, well-known features, structures, or operations are not shown or described in detail. Furthermore, the described features, structures, or operations may be combined in any suitable manner in one or more embodiments. It will also be readily understood that the components of the embodiments, as generally described and illustrated in the figures herein, could be arranged and designed in a wide variety of different configurations. For example, throughout this specification, any reference to “one embodiment,” “an embodiment,” or “the embodiment” means that a particular feature, structure, or characteristic described in connection with that embodiment is included in at least one embodiment. The quoted phrases, or variations thereof, as recited throughout this specification do not necessarily all refer to the same embodiment.

Several aspects of the embodiments disclosed herein may be implemented as software modules or components. As used herein, a software module or component may include any type of computer instruction or computer-executable code located within a memory device that is operable in conjunction with appropriate hardware to implement the programmed instructions. For instance, a software module or component may comprise one or more physical or logical blocks of computer instructions, which may be organized as a routine, program, object, component, data structure, etc., that performs one or more tasks or implements particular abstract data types.

In certain embodiments, a particular software module or component may comprise disparate instructions stored in different locations of a memory device, which together implement the described functionality of the module. A module or component may comprise a single instruction or many instructions and may be distributed over several different code segments, among different programs, and across several memory devices. Some embodiments may be practiced in a distributed computing environment where tasks are performed by a remote processing device linked through a communications network. Software modules or components may be located in local and/or remote memory storage devices in a distributed computing environment. In addition, data being tied or rendered together in a database record may be resident in the same memory device or across several memory devices and may be linked together in fields of a record in a database across a network.

Embodiments may be provided as computer program products, including a non-transitory machine-readable medium to store instructions that may be used to program a computer or other electronic device to perform the processes described herein. The non-transitory machine-readable medium may include but is not limited to, hard drives, floppy diskettes, optical disks, CD-ROMs, DVD-ROMs, ROMs, RAMS, EPROMs, EEPROMs, magnetic or optical cards, solid-state memory devices, or other types of media/machine-readable media suitable for storing electronic instructions. In some embodiments, the computer or another electronic device may include a processing device such as a microprocessor, microcontroller, logic circuitry, or the like. The processing device may further include one or more special-purpose processing devices such as an application-specific interface circuit (ASIC), PAL, PLA, PLD, field-programmable gate array (FPGA), or any other customizable or programmable device.

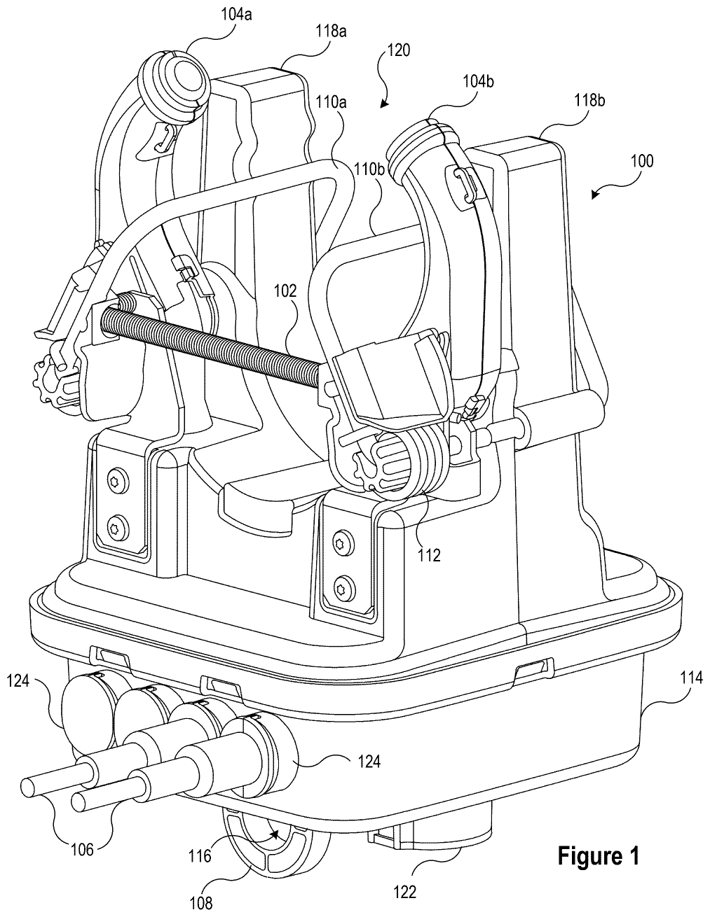

FIG. 1 illustrates a perspective view of a current sensor 100 in an open configuration consistent with embodiments of the present disclosure. A pair of fixed arms 118a, 118b may create at least a portion of channel 120 to receive an electric conductor (not shown). Fixed arms 118a, 118b may be part of a power-harvesting subsystem. The power harvesting subsystem may draw energy the electrical conductor, and the energy may be used to power current sensor 100. Moveable arms 104a, 104b may form a loop that at least partially surrounds an electrical conductor in an closed configuration. Current sensor 100 includes a spring 102 that may hold moveable arms 104a, 104b in an open configuration.

Current sensor 100 may electromagnetically couple to an electrical conductor (not shown), such that a current flowing through the electrical conductor includes a proportional current in components disposed within moveable arms 104a, 104b. The proportional current may be monitored by current sensor 100 to determine a current flowing through the electrical conductor. In various embodiments, moveable arms 104a, 104b may comprise a Rowowski coil.

A housing 114 may house components to enable communication between current sensor 100 and other electric power system elements. Such components may include circuitry to represent the current measured by current sensor 100 and to communicate such measurements to an IED or other device in the electric power system. Housing 114 may include a plurality of outlets 124. Information generated by current sensor 100 may be transmitted to other components via cables 106. Cables 106 may enter housing 114 via outlets 124.

Retention elements 110a, 110b may be coupled to moveable arms 104a, 104b and may secure current sensor 100 to the electrical conductor. Retention element 110b may be coupled to tension element 112. Tension element 112 may exert a force tending to cause moveable arm 104b and retention element 110b to rotate counterclockwise. Although not visible in FIG. 1, retention element 110a and moveable arm 104a may also be associated with a tension element similar to tension element 112. The forces exerted by the tension elements on retention elements 110a, 110b may mount current sensor 100 to an electrical conductor disposed in channel 120.

Current sensor 100 includes a hot stick connector 108. Hot stick connector 108 may comprise an eye 116. A hot stick may engage with hot stick connector 108 and eye 116 to allow installation of current sensor 100 on an energized conductor from a safe working distance. In various embodiments, hot stick connector 108 may be positioned on housing 114 to maximize the distance between the operator and the electrical conductor during the installation of the current monitor, and thus improve safety.

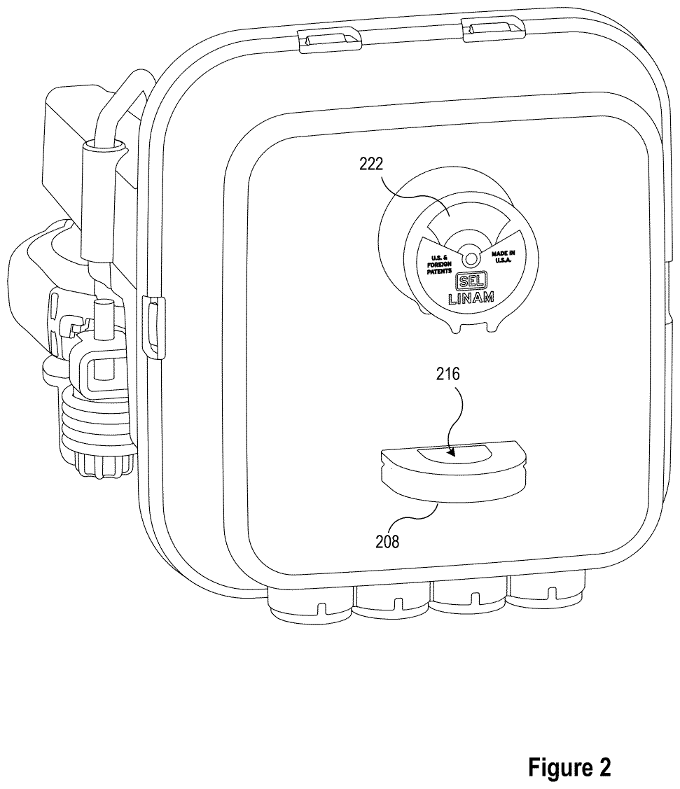

FIG. 2 illustrates a perspective view of a current sensor comprising a fault indicator 222 consistent with embodiments of the present disclosure. In various embodiments, fault indicator 222 may provide a visual indicator of an over-current condition. Upon the occurrence of an over-current condition, fault indicator 222 may toggle between a faulted state and a normal (not faulted) state. In one specific embodiment, fault indicator 222 may be red for a faulted state and white for a normal state. Alternatively, fault indicator 222 may illuminate in one color for a faulted condition and another color for a normal (not faulted) condition. Other types of faults may also be detected by current sensor 100 and communicated to other components in the electric power system.

FIG. 2 also illustrates a hot stick connector 208 and an eye 216 in the hot stick connector. An operator may grasp current sensor 200 using hot stick connector 208 and may use the hot stick to install current sensor 200 on an energized conductor. The hot stick may be configured to couple to hot stick connector 208 while the operator remains a safe distance away. The hot stick may further allow the operator to release the hot stick from hot stick connector 208 once current sensor 200 is installed on the live conductor from a safe distance.

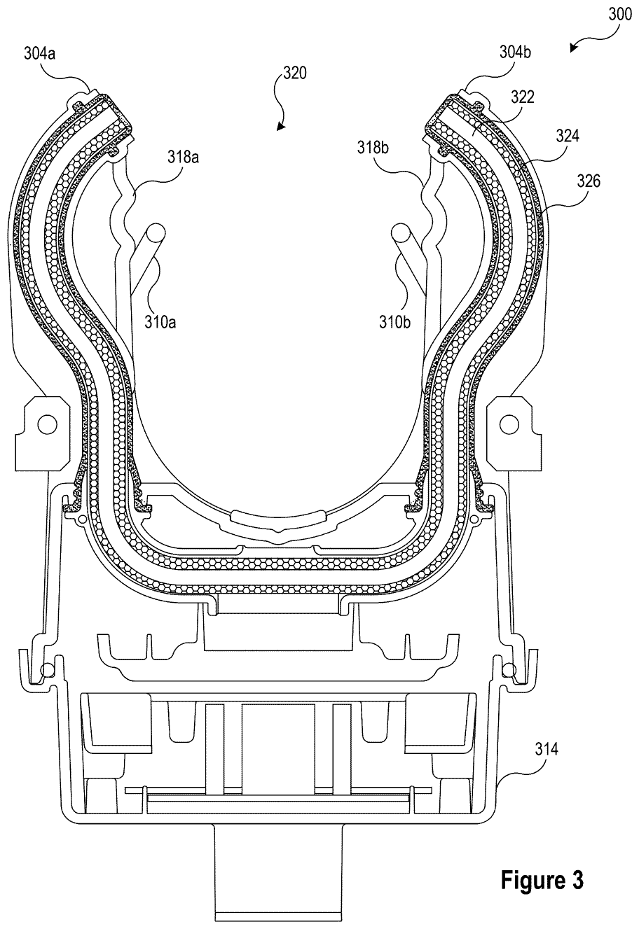

FIG. 3 illustrates a cross-sectional view of a current sensor 300 in an open configuration consistent with embodiments of the present disclosure. Moveable arms 304a, 304b are separated and form channel 320. Channel 320 may also be formed by fixed arms 318a and 318b. An electrical conductor (not shown) to be monitored may be disposed in channel 320. Moveable arms 304a, 304b may be transitioned to a closed configuration around an electrical conductor. In the closed configuration, moveable arms 304a, 304b may at least partially surround the electrical conductor.

Moveable arms 304a, 304b comprise a current sensor. In the illustrated embodiment, the current sensor comprises a Rogowski coil. The Rogowski coil comprises a hollow core322, and a non-magnetic element 324. A winding (not shown) may be disposed around the non-magnetic element 324. The winding is wound evenly along the length of non-magnetic element 322. A voltage induced in winding 324 is proportional to the rate of change of the current flowing through a conductor surrounded by the Rogowski coil. In some embodiments the voltage generated by the Rogowski coil may be processed by circuitry disposed in a housing 314. In other embodiments, the Rogowski may be in electrical communication through a wire to another device that processes the signal. A flexible boot 326 may be disposed around moveable arms 304a, 304b to provide environmental sealing.

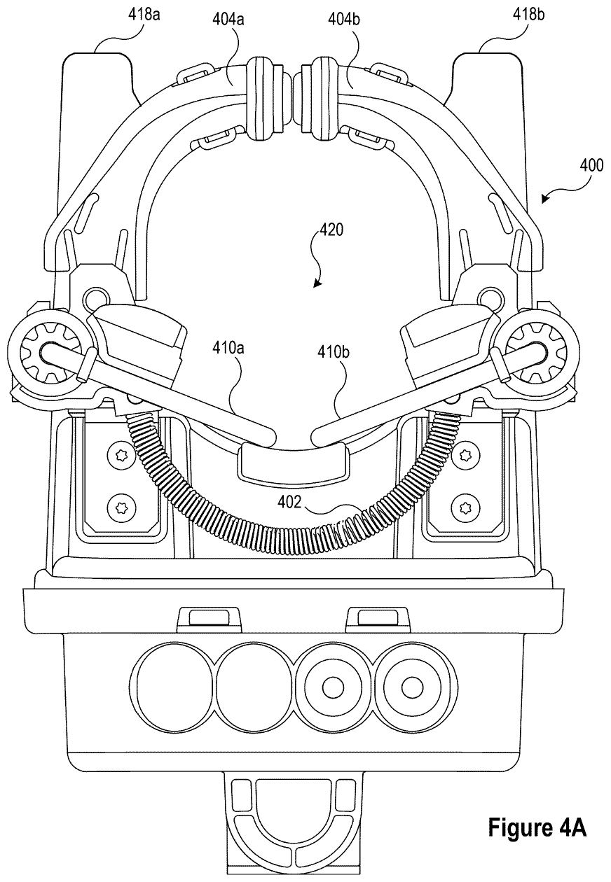

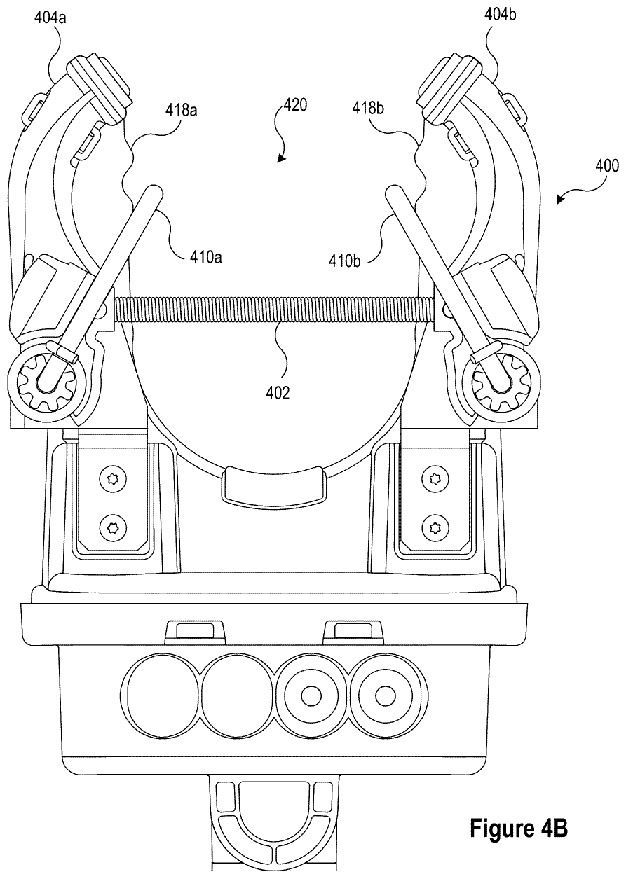

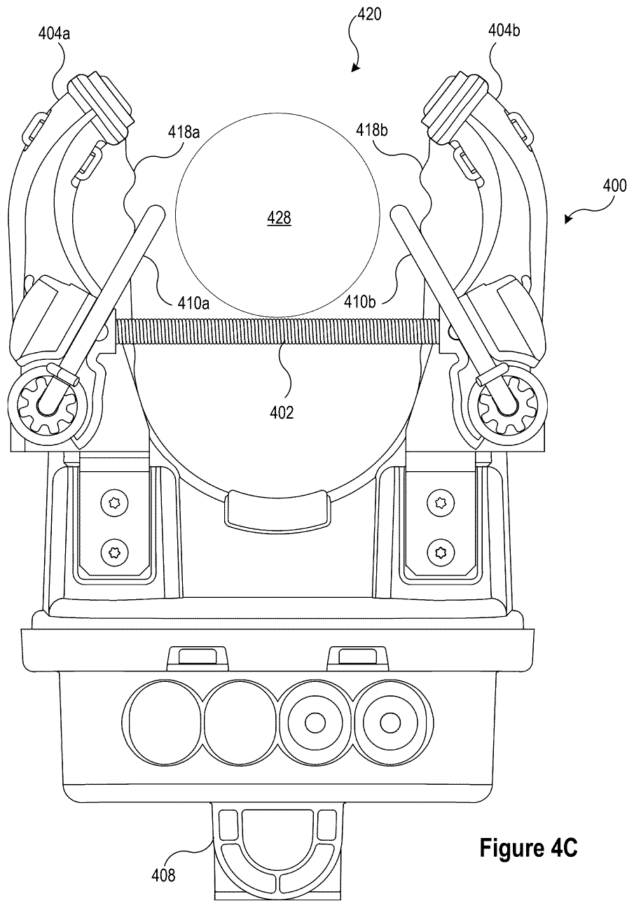

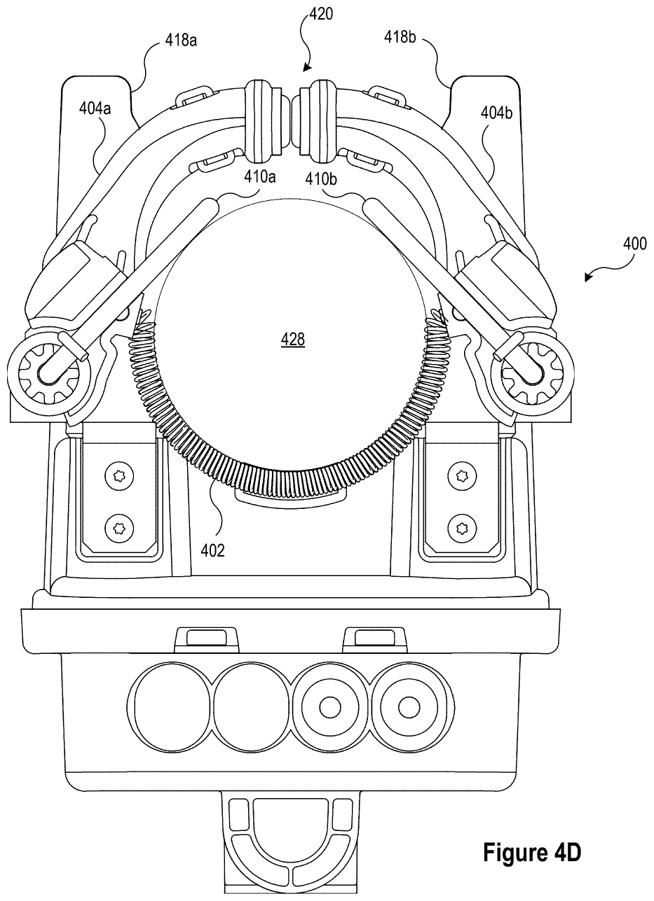

FIG. 4A illustrates a bottom view of a current sensor 400 in a closed configuration consistent with embodiments of the present disclosure. The closed configuration illustrated in FIG. 4A may be the default configuration (i.e., the configuration into which current sensor 400 would revert without outside influence. As illustrated, moveable arms 404a, 404b are disposed on opposite sides of channel 420. Retention elements 410a, 410b rest against the bottom of channel 420, and spring 402 forms an arc.

FIG. 4B illustrates a bottom view of the current sensor 400 of FIG. 4A in an open configuration consistent with embodiments of the present disclosure. An operator may reconfigure current sensor 400 from the closed configuration shown in FIG. 4A to the open configuration shown in FIG. 4B by pulling retention elements 410a, 410b apart. As retention elements 410a, 410b open, they will drive moveable arms 404a, and 404b apart. The exertion of such a force will cause spring 402 to straighten. Although not shown in FIG. 4B, tension elements may resist the transition from the closed state shown in FIG. 4A, and the open configuration shown in FIG. 4B. Once straightened, spring 402 may hold current sensor 400 in the open configuration; however, the tension stored by the tension elements may cause current sensor 400 to transition to the closed configuration when an electrical conductor is pressed into channel 420.

FIG. 4C illustrates a bottom view of current sensor 400 in an open configuration and receiving a conductor in channel 420 consistent with embodiments of the present disclosure. A hot stick (not shown) may be attached to hot stick connector 408 and used to maneuver current sensor 400 into the position shown with respect to a conductor 428. As illustrated in FIG. 4C, conductor 428 is entering channel 420. The configuration illustrated in FIG. 4C may be achieved with the operator located a safe distance away from conductor 428 and insulated from the electrical energy carried by conductor 428 by the hot stick.

FIG. 4D illustrates a bottom view of current sensor 400 in a closed configuration and mounted to a conductor consistent with embodiments of the present disclosure. An operator may transition from the configuration illustrated in FIG. 4C to the configuration illustrated in FIG. 4D by pressing current sensor 400 against conductor 428 using the hot stick coupled to hot stick connector 408. The force exerted by conductor 428 against spring 402 causes spring 402 to buckle. As spring 402 buckles, it releases the tension stored in the tensioners (not shown) and moveable arms 404a, 404b and retention elements 410a, 410b rotate inward around conductor 428. Once current sensor 400 is mounted to conductor 428, as shown in FIG. 4D, the hot stick may be disengaged from hot stick connector 408.

The installation process illustrated in FIGS. 4A-4D may be performed without de-energizing conductor 428 and without posing a risk to the operator installing current sensor 400. Once current sensor 400 is installed, it may be connected to a variety of types of equipment in an electric power system and used to monitor operation of the system.

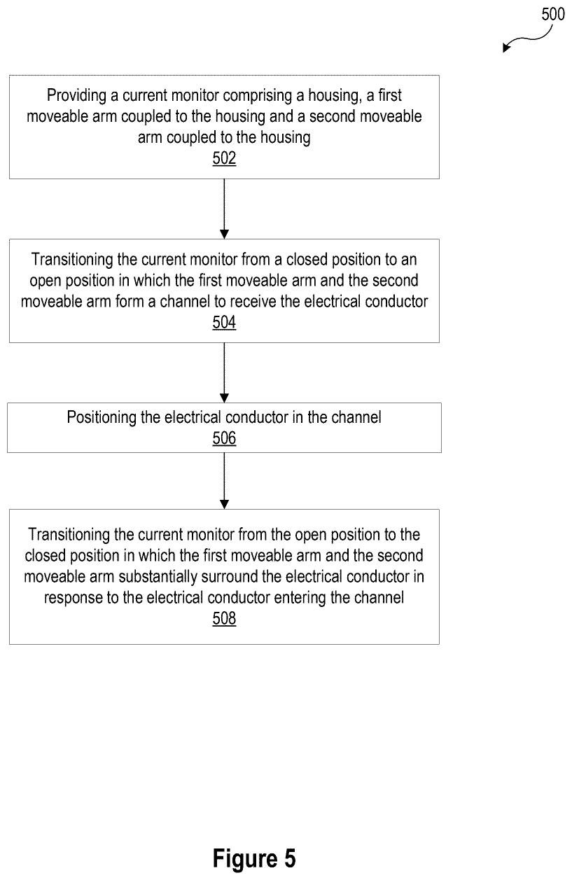

FIG. 5 is a flowchart of an example method 500 of mounting a current monitor to an energized electrical conductor in an electric power system consistent with embodiments of the present disclosure. At 510, an operator provides a current monitor comprising a housing, a first moveable arm coupled to the housing, and a second moveable arm coupled to the housing. FIGS. 1-4 illustrate examples of current monitors that may be used in connection with method 500.

At 520, an operator may transition the current monitor from a closed configuration to an open configuration. In the open configuration, the first moveable arm and the second moveable arm form a channel to receive the electrical conductor. At 530, the operator may position the electrical conductor in the channel. At 540, the current monitor may transition from the open configuration to the closed configuration in which the first moveable arm and the second moveable arm at least partially surround the electrical conductor in response to the electrical conductor entering the channel.

In various embodiments, an operator may couple a hot stick to a hot stick connector disposed on the housing of the current monitor. The operator may exert a force on the current monitor and against the electrical conductor using the hot stick to cause the current monitor to transition from the open configuration to the closed configuration. After the current monitor is mounted to the electrical conductor, the operator may decouple the hot stick from the hot stick connector.

While specific embodiments and applications of the disclosure have been illustrated and described, it is to be understood that the disclosure is not limited to the precise configuration and components disclosed herein. Various modifications, changes, and variations apparent to those of skill in the art may be made in the arrangement, operation, and details of the methods and systems of the disclosure without departing from the spirit and scope of the disclosure.

What is claimed:

1. A current monitor configured to be mounted to an energized electrical conductor in an electric power system, the current monitor comprising:
a housing;
a first moveable arm coupled to the housing;
a second moveable arm coupled to the housing, the first moveable arm and the second moveable arm configurable in an open configuration and a closed configuration; and
a current sensor disposed in the moveable first arm and the second moveable arm to generate a signal output representing a current flow in the energized electrical conductor;
wherein the first moveable arm and the second moveable arm form a channel to receive the electrical conductor in the open configuration and transition to a closed configuration in which the first moveable arm and the second moveable arm at least partially surround the electrical conductor in response to the electrical conductor entering the channel.

2. The current monitor of claim 1, further comprising a hot stick connector disposed on the housing;
wherein the hot stick connector is disposed on the housing such that an operator can exert a force on the current monitor and against the electrical conductor using a hot stick to cause the current monitor to transition from the open configuration to the closed configuration.

3. The current monitor of claim 2, wherein the hot stick connector disposed on the housing is positioned to maximize a distance between the operator and the electrical conductor during installation of the current monitor.

4. The current monitor of claim 1, wherein the current sensor comprises a Rogowski coil.

5. The current monitor of claim 1, further comprising a first fixed arm and a second fixed arm;
wherein the first fixed arm and the second fixed arm form at least a portion of the channel.

6. The current monitor of claim 1, further comprising a first retention element and a second retention element;
wherein the first retention element and the second retention element form at least a portion of the channel in the open configuration and at least partially surround the energized electrical conductor in the closed configuration.

7. The current monitor of claim 6, wherein the first retention element and the second retention element exert a force against the electrical conductor in the closed configuration, and the force mounts the current monitor to the energized electrical conductor.

8. The current monitor of claim 1, further comprising a tension element coupled to the first moveable arm and the second moveable arm to store potential energy when the first moveable arm and the second moveable arm transition from the closed configuration to the open configuration and to release the stored energy when the first moveable arm and the second moveable arm transition from the open configuration to the closed configuration.

9. The current monitor of claim 1, further comprising a spring disposed between the first moveable arm and the second moveable arm;
wherein the spring is configured to maintain the first moveable arm and the second moveable arm in the open configuration and to allow the first moveable arm and the second moveable arm to transition to the closed configuration when the electrical conductor contacts the spring in the channel.

10. The current monitor of claim 1, further comprising a fault indicator mounted to the housing.

11. Method of mounting a current monitor to an energized electrical conductor in an electric power system, method comprising:
providing the current monitor comprising:
a housing;
a first moveable arm coupled to the housing;
a second moveable arm coupled to the housing; and
a current sensor disposed in the moveable first arm and the second moveable arm to generate a signal output representing a current flow in the energized electrical conductor;
transitioning the current monitor from a closed configuration to an open configuration in which the first moveable arm and the second moveable arm form a channel to receive the electrical conductor;
positioning the electrical conductor in the channel; and
transitioning the current monitor from the open configuration to the closed configuration in which the first moveable arm and the second moveable arm at least partially surround the electrical conductor in response to the electrical conductor entering the channel.

12. The method of claim 11, further comprising:
coupling a hot stick to a hot stick connector disposed on the housing; and
exerting a force on the current monitor and against the electrical conductor using the hot stick to cause the current monitor to transition from the open configuration to the closed configuration.

13. The method of claim 12, wherein the hot stick connector disposed on the housing is positioned to maximize a distance between an operator and the electrical conductor during installation of the current monitor.

14. The method of claim 11, wherein the current sensor comprises a Rogowski coil.

15. The method of claim 11, wherein the current monitor further comprises a first fixed arm and a second fixed arm and the first fixed arm and the second fixed arm form at least a portion of the channel.

16. The method of claim 11, wherein the current monitor further comprises a first retention element and a second retention element and the first retention element and the second retention element form at least a portion of the channel in the open configuration and at least partially surround the energized electrical conductor in the closed configuration.

17. The method of claim 16, wherein the first retention element and the second retention element exert a force against the electrical conductor in the closed configuration, and the force mounts the current monitor to the energized electrical conductor.

18. The method of claim 11, further comprising:
storing potential energy using a tension element coupled to the first moveable arm and the second moveable arm to store potential energy when the first moveable arm and the second moveable arm transition from the closed configuration to the open configuration; and
releasing the stored energy when the first moveable arm and the second moveable arm transition from the open configuration to the closed configuration.

19. The method of claim 11, wherein the current monitor further comprises a spring disposed between the first moveable arm and the second moveable arm;
wherein the spring maintains the first moveable arm and the second moveable arm in the open configuration and allows the first moveable arm and the second moveable arm to transition to the closed configuration when the electrical conductor contacts the spring in the channel.

20. The method of claim 11, further comprising:
generating an indication of a fault; and
displaying the indication of the fault using a fault indicator mounted to the housing.
